(19) United States
(12) Patent Application Publication
(10) Pub. No.: US 2026/0363112 A1
(43) Pub. Date: Nov. 12, 2026

(54) DISPLAY DEVICE AND ELECTRONIC DEVICE INCLUDING THE SAME

(71) Applicant: Samsung Display Co., Ltd., Yongin-si (KR)

(72) Inventors: Hyun Seok KO, Yongin-si (KR); Dong Youb LEE, Yongin-si (KR); Chang Woo WON, Yongin-si (KR); Jin Uk HWANG, Yongin-si (KR)

(21) Appl. No.: 19/383,454

(22) Filed: Nov. 7, 2025

(30) Foreign Application Priority Data
May 8, 2025 (KR) 10-2025-0059983

(51) Int. Cl. H10W 70/65; H10W 90/00

(52) U.S. Cl. CPC H10W 70/65; H10W 90/00

(57) ABSTRACT

A display device includes a display panel including a display area and a non-display area, an integrated circuit in the non-display area, a pad part in the non-display area and spaced from the integrated circuit, a circuit board on the integrated circuit and the pad part and including a main body portion spaced from the integrated circuit, and a connecting body portion extending straight from the main body portion and spaced from the pad part, an adhesive part adjacent to the integrated circuit, on the main body portion, and between the display panel and the circuit board, and a compensation part between the circuit board and the pad part.

### CROSS-REFERENCE TO RELATED APPLICATION

The present application claims priority to, and the benefit of, Korean Patent Application Number 10-2025-0059983, filed on May 8, 2025, in the Korean Intellectual Property Office, the entire disclosure of which is incorporated herein by reference.

### BACKGROUND

### 1. Field

Aspects of some embodiments of the present disclosure relate to a display device and an electronic device including the display device.

### 2. Description of the Related Art

With the development of information technology, the importance of display devices, which provide a connection medium between users and information, has been emphasized. Owing to the importance of display devices, the use of various kinds of display devices, such as liquid crystal display devices, organic light-emitting display devices, and plasma display devices, has increased.

The above information disclosed in this Background section is only for enhancement of understanding of the background and therefore the information discussed in this Background section does not necessarily constitute prior art.

### SUMMARY

Aspects of some embodiments of the present disclosure include a display device and an electronic device including the display device, which may reduce or eliminate stress caused by a step of an integrated circuit.

A display device according to some embodiments of the present disclosure includes a display panel including a display area and a non-display area, an integrated circuit in the non-display area, a pad part in the non-display area and spaced from the integrated circuit, a circuit board on the integrated circuit and the pad part and including a main body portion spaced from the integrated circuit, and a connecting body portion extending straight from the main body portion and spaced from the pad part, an adhesive part adjacent to the integrated circuit, on the main body portion, and between the display panel and the circuit board, and a compensation part between the circuit board and the pad part.

The compensation part may be between the connecting body portion and the pad part.

The main body portion may include a first main body on the adhesive part, a second main body on the first main body and connected to the connecting body portion, and a third main body on the second main body.

The integrated circuit may have a first thickness, wherein the adhesive part contacts three sides of the integrated circuit and has a second thickness that is greater than the first thickness.

The integrated circuit may have a first thickness, wherein the adhesive part is spaced from the integrated circuit and has a second thickness that is less than the first thickness.

The main body portion may be spaced from the integrated circuit in a thickness direction, in a length direction, in a direction opposite to the length direction, and in a width direction, wherein the connecting body portion is spaced from the pad part in the thickness direction.

The main body portion may be spaced from the integrated circuit in a thickness direction, in a length direction, in a direction opposite the length direction, in a width direction, and in a direction opposite the width direction, wherein the connecting body portion is spaced from the pad part in the thickness direction.

A display device according to some embodiments of the present disclosure includes a display panel including a display area and a non-display area, an integrated circuit in the non-display area, a pad part in the non-display area and spaced from the integrated circuit, a circuit board on the integrated circuit and the pad part, and including a main body portion spaced from the integrated circuit, and a connecting body portion extending straight from the main body portion and on the pad part, and an adhesive part adjacent to the integrated circuit, on the main body portion, and between the display panel and the circuit board.

The connecting body portion may include a first connecting body extending straight from the main body portion, a second connecting body below the first connecting body, and an electrode between the second connecting body and the pad part.

The main body portion may include a first main body on the adhesive part, a second main body on the first main body and connected to the first connecting body, and a third main body on the second main body.

The integrated circuit may have a first thickness, wherein the adhesive part contacts three sides of the integrated circuit and has a second thickness that is greater than the first thickness.

The integrated circuit may have a first thickness, wherein the adhesive part is spaced from the integrated circuit and has a second thickness that is less than the first thickness.

The main body portion may be spaced from the integrated circuit in a thickness direction, in a length direction, in a direction opposite the length direction, and in a width direction.

The main body portion may be spaced from the integrated circuit in a thickness direction, in a length direction, in a direction opposite to the length direction, in a width direction, and in a direction opposite to the width direction.

The main body portion may include a first main body on the adhesive part and connected to the connecting body portion, a second main body on the first main body, and a third main body on the second main body.

The main body portion may be spaced from the integrated circuit in a thickness direction, in a length direction, in a direction opposite to the length direction, in a width direction, and in a direction opposite to the width direction.

The connecting body portion may include a first connecting body extending straight from the main body portion, a second connecting body below the main body portion and the first connecting body, and an electrode between the second connecting body and the pad part.

The main body portion may include a first main body on the adhesive part, a second main body on the first main body and connected to the first connecting body, and a third main body on the second main body.

The main body portion may be spaced from the integrated circuit in a thickness direction, in a length direction, in a direction opposite to the length direction, and in a width direction, wherein the second connecting body is spaced from the integrated circuit in a direction opposite to the width direction.

An electronic device according to some embodiments of the present disclosure includes a processor configured to provide input image data, and a display device configured to display an image based on the input image data and including a display panel including a display area and a non-display area, an integrated circuit in the non-display area, a pad part in the non-display area and spaced from the integrated circuit, a circuit board on the integrated circuit and the pad part and including a main body portion spaced from the integrated circuit, and a connecting body portion extending straight from the main body portion and spaced from the pad part, an adhesive part adjacent to the integrated circuit, on the main body portion, and between the display panel and the circuit board, and a compensation part between the circuit board and the pad part.

### BRIEF DESCRIPTION OF THE DRAWINGS

FIG. 1 schematically illustrates a display device according to some embodiments of the present disclosure.

FIG. 2 schematically illustrates a display device according to some embodiments of the present disclosure.

FIG. 3 is a cross-sectional view along the line I-I' of FIG. 1 according to some embodiments of the present disclosure.

FIG. 4 schematically illustrates a manufacturing process according to some embodiments of the present disclosure.

FIG. 5 schematically illustrates a manufacturing process according to some embodiments of the present disclosure.

FIG. 6 is a cross-sectional view along the line I-I' of FIG. 1 according to some embodiments of the present disclosure.

FIG. 7 is a cross-sectional view along the line I-I' of FIG. 1 according to some embodiments of the present disclosure.

FIG. 8 is a cross-sectional view along the I-I' line of FIG. 1 according to some embodiments of the present disclosure.

FIG. 9 is a cross-sectional view along the I-I' line of FIG. 1 according to some embodiments of the present disclosure.

FIG. 10 is a cross-sectional view along the I-I' line of FIG. 1 according to some embodiments of the present disclosure.

FIG. 11 is a cross-sectional view along the I-I' line of FIG. 1 according to some embodiments of the present disclosure.

FIG. 12 is a cross-sectional view along the I-I' line of FIG. 1 according to some embodiments of the present disclosure.

FIG. 13 schematically illustrates an electronic device according to some embodiments of the present disclosure.

FIG. 14 schematically illustrates an electronic device according to some embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

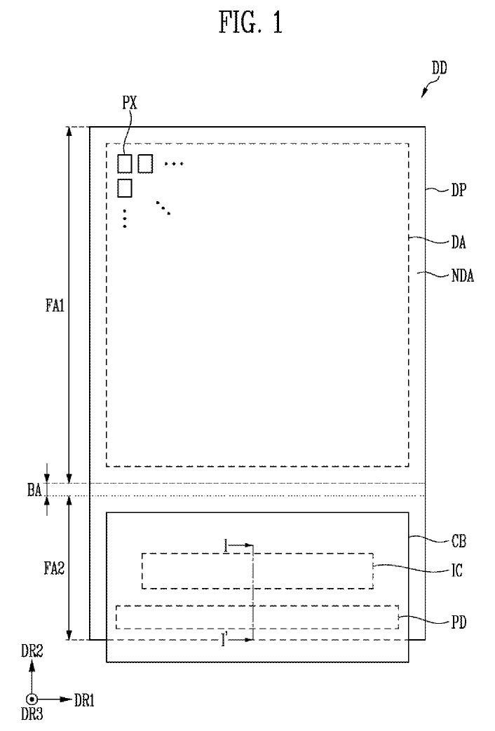

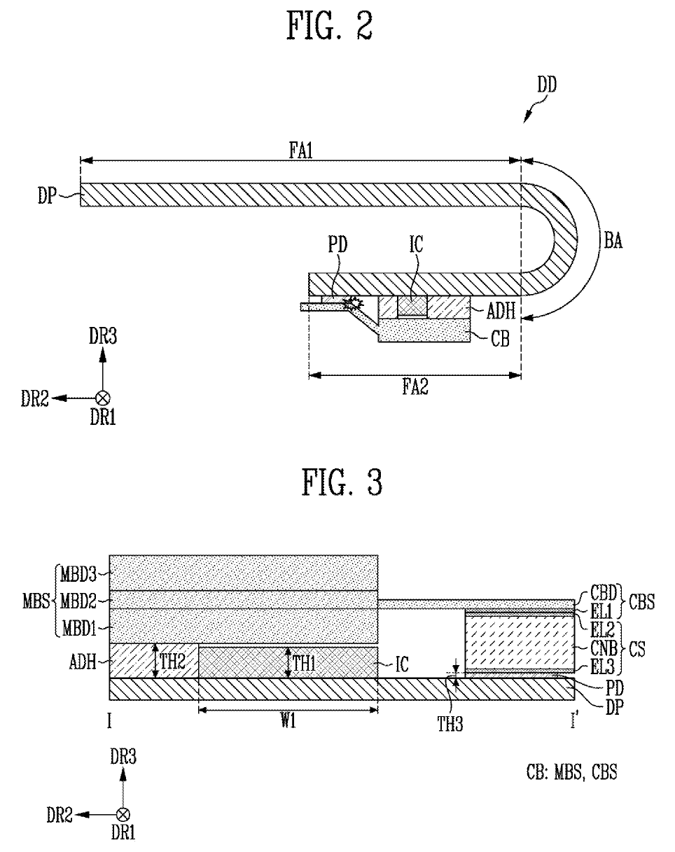

FIG. 1 schematically illustrates a display device according to some embodiments of the present disclosure. FIG. 2 schematically illustrates a display device according to some embodiments of the present disclosure.

Referring to FIG. 1, a display device DD may include a display panel DP, an integrated circuit IC, a pad part PD, and a circuit board CB. Referring to FIG. 2, the display device DD may further include an adhesive part ADH.

The display panel DP may include a first flat area FA1, a bending area BA, and a second flat area FA2. The bending area BA may be located between the first flat area FA1 and the second flat area FA2. The display panel DP may be bent or curved in the bending area BA.

The display panel DP may include a display area DA and a non-display area NDA. The display area DA may be located in the first flat area FA1. The display area DA may be an area for displaying an image and may include pixels PX. The non-display area NDA may be located in the first flat area FA1, the bending area BA, and the second flat area FA2. The non-display area NDA may be an area that does not display an image and may surround the display area DA.

The integrated circuit IC may be located in the second flat area FA2 and the non-display area NDA. The integrated circuit IC may generate and provide signals to the pixels PX that are suitable to drive the pixels PX. For example, the integrated circuit IC may be a display driver IC (DDI) and may include a gate driver, a data driver, and the like. The integrated circuit IC may be attached to the display panel DP via a chip-on-glass (COG) method, a chip-on-plastic (COP) method, or the like, but embodiments are not necessarily limited thereto.

The pad part PD may be located in the second flat area FA2 and the non-display area NDA. The pad part PD may be spaced apart from the integrated circuit IC. For example, the pad part PD may be spaced apart from the integrated circuit IC in a second direction DR2 (or, a width direction). The pad part PD may be electrically connected to the integrated circuit IC.

The circuit board CB may be located in the second flat area FA2 and the non-display area NDA. The circuit board CB may be electrically connected to the pad part PD and a processor. The circuit board CB may pass signals processed by the processor to an integrated circuit IC. For example, the circuit board CB may be a printed circuit board (PCB), a flexible printed circuit board (FPCB), or the like.

The adhesive part ADH may be located in the second flat area FA2 and the non-display area NDA. For example, the adhesive part ADH may be adjacent to the integrated circuit IC, surrounding the integrated circuit IC and located between the display panel DP and the circuit board CB. The adhesive part ADH may attach the circuit board CB to the display panel DP.

The circuit board CB may be positioned generally on the display panel DP. For example, the circuit board CB may be located on the integrated circuit IC and spaced apart from the integrated circuit IC. The circuit board CB may also extend in the second direction DR2 and may be positioned on the pad part PD. In cast that the circuit board CB is positioned on the integrated circuit IC and the circuit board CB is electrically connected to the pad part PD, a step may occur in the circuit board CB as shown in FIG. 2. The stress caused by a step difference may be concentrated on the circuit board CB adjacent to the pad part PD, which may cause damage to the pad part PD. Also, the thicker the circuit board CB, then the larger the step, which may cause more stress damage. In addition, the adhesive part ADH may be attached to the display panel DP after lifting the circuit board CB on the integrated circuit IC, and in this process, stress is concentrated to the circuit board CB adjacent to the pad part PD, which may cause process failure.

In this way, a step difference in the circuit board CB may cause a defect in the display device DD. The following describes embodiments that may reduce or prevent the likelihood of component damage, process defects, and the like by eliminating a step while maintaining a position and connection structure of the circuit board CB.

FIG. 3 is a cross-sectional view along the line I-I' of FIG. 1 according to some embodiments of the present disclosure.

Referring to FIG. 3, an integrated circuit IC may be located on a display panel DP (as used herein, “located on” or “on” may mean “above” or “below”). The integrated circuit IC may have a thickness TH1 (or, first thickness) and a first width W1.

The adhesive part ADH may be located on the display panel DP and adjacent to the integrated circuit IC. The adhesive part ADH may be located on three sides (or surfaces) of the integrated circuit IC. For example, the adhesive part ADH may be located in, or may extend in, a first direction DR1 (or, a length direction), in a direction opposite the first direction DR1, and in a second direction DR2 relative to the integrated circuit IC. The first direction DR1 and the second direction DR2 may cross. That is, the adhesive part ADH may not be located in an opposite direction of the second direction DR2 relative to the integrated circuit IC. The adhesive part ADH may contact three sides of the integrated circuit IC. The adhesive part ADH may have a thickness TH2 (or, a second thickness) that is greater than the thickness TH1 of the integrated circuit IC.

The pad part PD may be located on the display panel DP, and may be spaced apart from the integrated circuit IC. The pad part PD may have a thickness TH3 (or, a third thickness) that is less than the thickness TH1 of the integrated circuit IC.

The circuit board CB may be located on the integrated circuit IC and the pad part PD. The circuit board CB may be attached to the display panel DP by the adhesive part ADH. The circuit board CB may be spaced apart from the integrated circuit IC and the pad part PD in a third direction DR3 (or, a thickness direction). The third direction DR3 may cross the first direction DR1 and the second direction DR2. In the third direction DR3, a distance between the circuit board CB and the integrated circuit IC may be less than a distance between the circuit board CB and the pad part PD. The circuit board CB may include a main body portion MBS and a connecting body portion CBS.

The main body portion MBS may be attached to the display panel DP by the adhesive part ADH, and may be located on the integrated circuit IC. The main body portion MBS may be spaced apart from the integrated circuit IC in the third direction DR3. The main body portion MBS may include multiple layers. For example, the main body portion MBS may include a first main body MBD1, a second main body MBD2 located on top of the first main body MBD1, and a third main body MBD3 located on top of the second main body MBD2.

The first main body MBD1, the second main body MBD2, and the third main body MBD3 may each constitute an electronic circuit, and may be electrically connected to each other. The first main body MBD1, the second main body MBD2, and the third main body MBD3 may each include multiple layers. For example, the first main body MBD1 may include three layers, the second main body MBD2 may include two layers, and the third main body MBD3 may include three layers. However, embodiments are not necessarily limited thereto.

The connecting body portion CBS may be connected to the main body portion MBS. The connecting body portion CBS may extend straight from the main body portion MBS (as used herein, “straight” may mean “generally straight”). For example, the connecting body portion CBS may extend from the main body portion MBS in the opposite direction of the second direction DR2. The connecting body portion CBS may include a connecting body CBD and an electrode EL1.

The connecting body CBD may be connected to the second main body MBD2. For example, the connecting body CBD may be connected to the second main body MBD2, which is an intermediate layer of the main body portion MBS, in consideration of cost, yield, and the like, but embodiments are not necessarily limited thereto. The connecting body CBD may extend straight from the second main body MBD2. For example, the connecting body CBD may extend from the second main body MBD2 in the opposite direction of the second direction DR2. The connecting body CBD may be spaced apart from the pad part PD in the third direction DR3. The connecting body CBD may include an electronic circuit, and may be electrically connected to the second main body MBD2.

The electrode EL1 may be located below the connecting body CBD. Above and below the connecting body CBD, a protective film may be placed to block the ingress of foreign matter or the like.

The compensation part CS may be located between the circuit board CB and the pad part PD. The compensation part CS may electrically connect the circuit board CB and the pad part PD, and may eliminate a step difference caused by a layout structure of the circuit board CB and the thickness difference between the integrated circuit IC and the pad part PD. For example, the connecting body portion CBS may extend straight without a step due to the compensation part CS located on the pad part PD. This allows the stress acting on the circuit board CB located on the pad part PD to be distributed and reduced or eliminated. The compensation part CS may have a thickness suitable to reduce or eliminate the step, and the thickness of the compensation part CS may be varied depending on the design.

The compensation part CS may include a connection board CNB, an electrode EL2 located on the connection board CNB, and an electrode EL3 located below the connection board CNB.

The electrode EL3 may be located between the pad part PD and the connection board CNB. The electrode EL3 may electrically connect the pad part PD and the connection board CNB.

The connection board CNB may be located on the electrode EL3. The connection board CNB may constitute an electronic circuit, and may electrically connect the electrode EL2 and the electrode EL3.

The electrode EL2 may be located between the connection board CNB and the electrode EL1 of the connecting body portion CBS. The electrode EL2 may electrically connect the electrode EL1 and the connection board CNB.

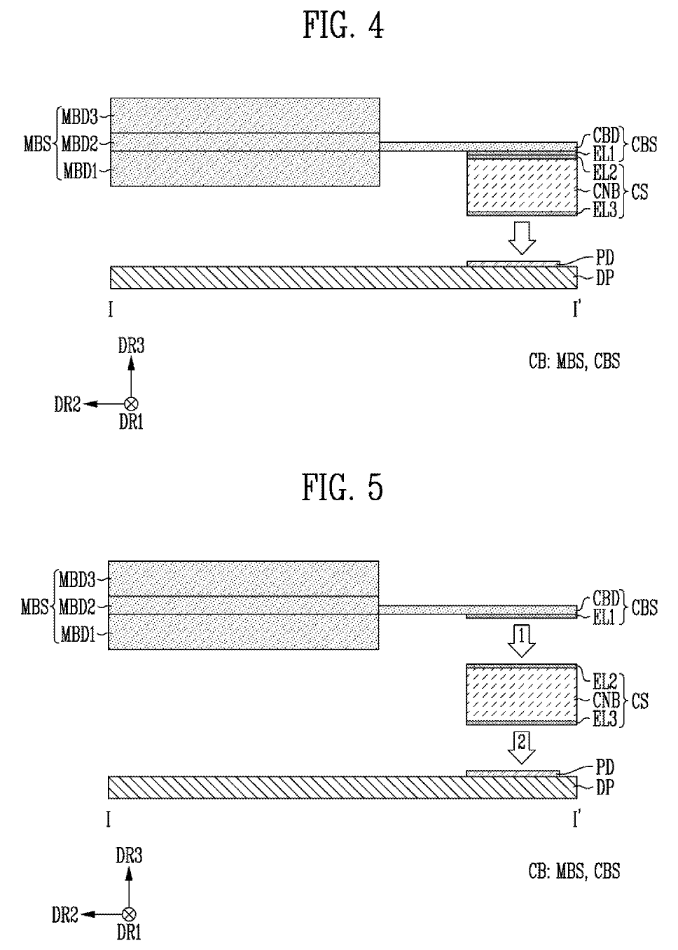

FIG. 4 schematically illustrates a manufacturing process according to some embodiments of the present disclosure. FIG. 5 schematically illustrates a manufacturing process according to some embodiments of the present disclosure.

Referring to FIG. 4, the compensation part CS may be manufactured integrally with the circuit board CB. The compensation part CS attached to the circuit board CB may be pressed against the pad part PD.

Referring to FIG. 5, the compensation part CS may be manufactured separately from the circuit board CB. The circuit board CB may be firstly pressed onto the compensation part CS, and the compensation part CS attached to the circuit board CB may be secondly pressed onto the pad part PD.

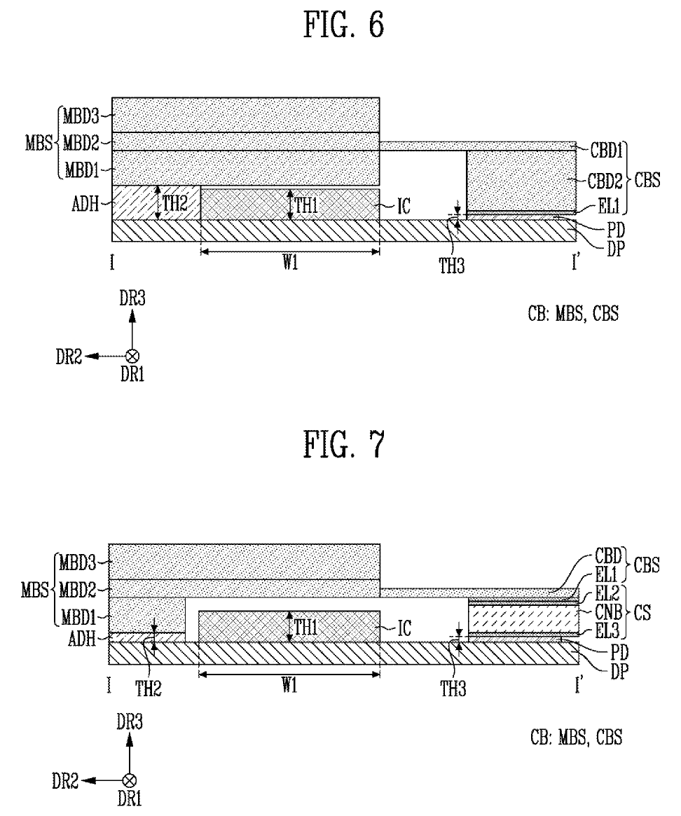

FIG. 6 is a cross-sectional view along the line I-I' of FIG. 1 according to some embodiments of the present disclosure. In FIG. 6, the description that overlap with FIG. 3 will be shortened or omitted.

Referring to FIG. 6, the connecting body portion CBS may include multiple layers. The connecting body portion CBS may include a first connecting body CBD1, a second connecting body CBD2, and an electrode EL1.

The first connecting body CBD1 may be connected to the second main body MBD2. The first connecting body CBD1 may extend straight from the second main body MBD2. For example, the first connecting body CBD1 may extend from the second main body MBD2 in the opposite direction of the second direction DR2. The first connecting body CBD1 may constitute an electronic circuit, and may be electrically connected to the second main body MBD2. Above and below the first connecting body CBD1, a protective film may be located to block the ingress of foreign matter or the like.

The second connecting body CBD2 may be located below the first connecting body CBD1. The second connecting body CBD2 may electrically connect the circuit board CB and the pad part PD, and may eliminate a step difference caused by the layout structure of the circuit board CB and the thickness difference between the integrated circuit IC and the pad part PD. For example, the first connecting body CBD1 may extend straight without a step due to the second connecting body CBD2 being located on the pad part PD. This may distribute and reduce or eliminate stresses acting on the circuit board CB located on the pad part PD. The second connecting body CBD2 may have a thickness suitable to reduce or eliminate the step, and a thickness of the second connecting body CBD2 may be varied according to the design. In this way, the stress caused by the step may be reduced or eliminated by changing the design of the circuit board CB (or the connecting body portion CBS) without introducing the compensation part CS (see FIG. 3).

The electrode EL1 may be located below the second connecting body CBD2. The electrode EL1 may be located between the second connecting body CBD2 and the pad part PD. The electrode EL1 may electrically connect the pad part PD and the second connecting body CBD2.

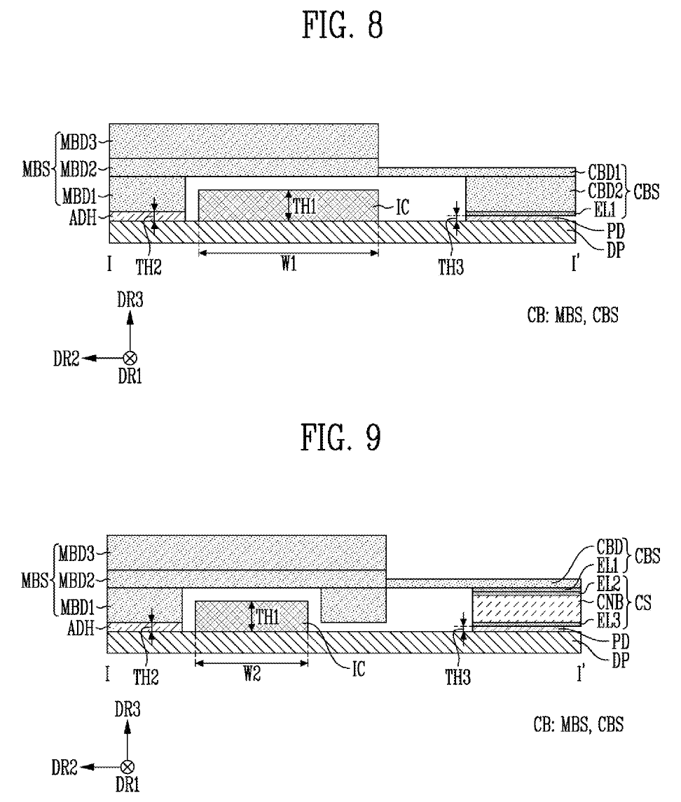

FIG. 7 is a cross-sectional view along the line I-I' of FIG. 1 according to some embodiments of the present disclosure. FIG. 8 is a cross-sectional view along the line I-I' of FIG. 1, according to some embodiments of the present disclosure. With reference to FIGS. 7 and 8, descriptions that overlap with FIGS. 3 and 6 will be shortened or omitted.

Referring to FIGS. 7 and 8, the adhesive part ADH may be spaced apart from three sides of the integrated circuit IC. For example, the adhesive part ADH may be spaced apart from the integrated circuit IC in the first direction DR1, in the direction opposite the first direction DR1, and in the second direction DR2. This may reduce interference between the circuit board CB and the integrated circuit IC located on the adhesive part ADH. The thickness TH2 of the adhesive part ADH may be less than the thickness TH1 of the integrated circuit IC. As the size of the adhesive part ADH decreases, the area occupied by the adhesive part ADH may decrease, thereby freeing up space.

The main body portion MBS may surround four sides of the integrated circuit IC. For example, the first main body MBD1 may be located in the first direction DR1, in the opposite direction of the first direction DR1, and in the second direction DR2 relative to the integrated circuit IC. For example, the second main body MBD2 may be located in the third direction DR3 relative to the integrated circuit IC.

The main body portion MBS may be spaced apart from the four sides of the integrated circuit IC. For example, the first main body MBD1 may be spaced apart from the integrated circuit IC in the first direction DR1, in the direction opposite to the first direction DR1, and in the second direction DR2. For example, the second main body MBD2 may be spaced apart from the integrated circuit IC in the third direction DR3. In this way, interference between the circuit board CB and the integrated circuit IC may be reduced by changing the design of the main body portion MBS.

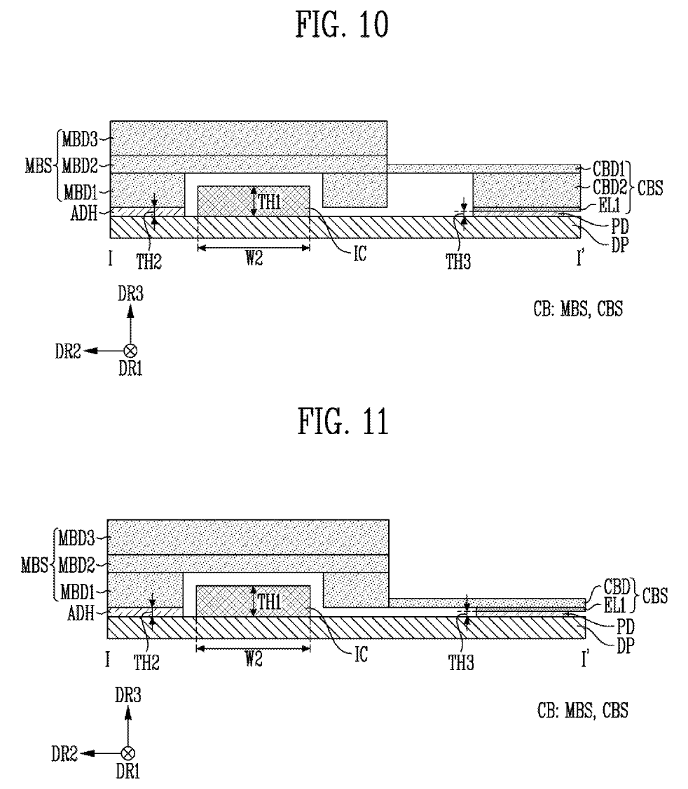

FIG. 9 is a cross-sectional view along the I-I' line of FIG. 1 according to some embodiments of the present disclosure. FIG. 10 is a cross-sectional view along the I-I' line of FIG. 1 according to some embodiments of the present disclosure. With reference to FIGS. 9 and 10, descriptions that overlap with FIGS. 3, 6 - 8 will be shortened or omitted.

Referring to FIGS. 9 and 10, the integrated circuit IC may have a second width W2 that is less than the first width W1 (see FIG. 3).

The main body portion MBS may surround five sides of the integrated circuit IC. For example, the first main body MBD1 may be located in the first direction DR1, in an opposite direction of the first direction DR1, in the second direction DR2, and in the opposite direction of the second direction DR2 relative to the integrated circuit IC. For example, the second main body MBD2 may be located in the third direction DR3 relative to the integrated circuit IC. The main body portion MBS may be spaced apart from the five sides of the integrated circuit IC. For example, the first main body MBD1 may be spaced apart from the integrated circuit IC in the first direction DR1, in the direction opposite of the first direction DR1, in the second direction DR2, and in the direction opposite of the second direction DR2. For example, the second main body MBD2 may be spaced apart from the integrated circuit IC in the third direction DR3. As such, the main body portion MBS may constitute a cap structure covering the integrated circuit IC.

FIG. 11 is a cross-sectional view along the I-I' line of FIG. 1 according to some embodiments of the present disclosure. In FIG. 11, descriptions that are redundant with FIG. 10 will be shortened or omitted.

Referring to FIG. 11, the connecting body CBD may be connected to the first main body MBD1. The connecting body CBD may extend straight from the first main body MBD1. For example, the connecting body CBD may extend from the first main body MBD1 in the opposite direction of the second direction DR2. That is, the connecting body CBD may be connected to the first main body MBD1, which is a lower layer of the main body portion MBS. This may reduce or eliminate the stress caused by the step, without introducing the compensation part CS (see FIG. 3) or changing the design of the circuit board CB (or, the connecting body portion CBS).

The electrode EL1 may be located on the pad part PD. The electrode EL1 may electrically connect the connecting body CBD and the pad part PD.

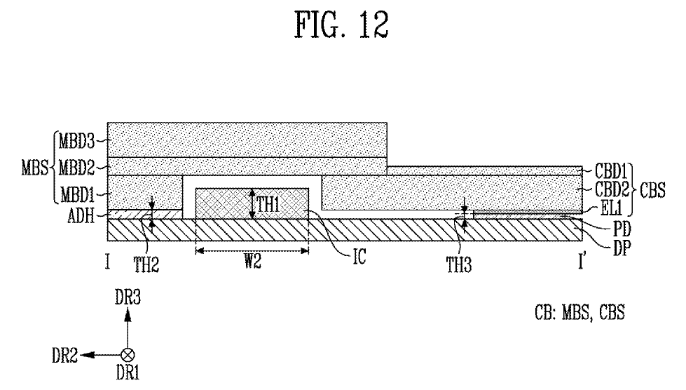

FIG. 12 is a cross-sectional view along the I-I' line of FIG. 1 according to some embodiments of the present disclosure. Referring to FIG. 12, descriptions that overlap with FIGS. 6 and 10 may be shortened or omitted.

Referring to FIG. 12, the main body portion MBS may surround four sides of the integrated circuit IC. For example, the first main body MBD1 may be located in the first direction DR1, in the opposite direction of the first direction DR1, and in the second direction DR2 relative to the integrated circuit IC. For example, the second main body MBD2 may be located in the third direction DR3 relative to the integrated circuit IC. The main body portion MBS may be spaced apart from the four sides of the integrated circuit IC. For example, the first main body MBD1 may be spaced apart from the integrated circuit IC in the first direction DR1, in the direction opposite to the first direction DR1, and in the second direction DR2. For example, the second main body MBD2 may be spaced apart from the integrated circuit IC in the third direction DR3.

The second connecting body CBD2 may be located below the first connecting body CBD1 and the second main body MBD2. The second connecting body CBD2 may be electrically connected to the first connecting body CBD1 and the second main body MBD2. The second connecting body CBD2 may surround one side of the integrated circuit IC. For example, the second connecting body CBD2 may be located in an opposite direction of the second direction DR2 relative to the integrated circuit IC. The second connecting body CBD2 may be spaced apart from one side of the integrated circuit IC. For example, the second connecting body CBD2 may be spaced apart from the integrated circuit IC in the opposite direction of the second direction DR2. As such, the second connecting body CBD2 may constitute a cap structure that covers the integrated circuit IC together with the main body portion MBS.

The display device according to embodiments may be applied to various electronic devices. The electronic device may include the display device described above, and may further include modules or devices having other additional functions in addition to the display device.

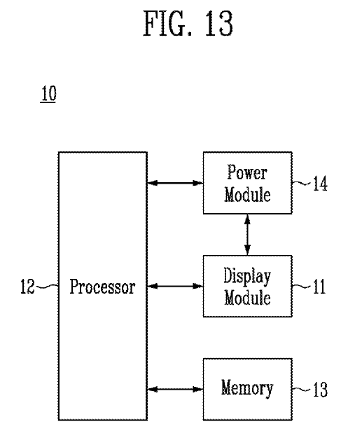

FIG. 13 schematically illustrates an electronic device according to some embodiments of the present disclosure.

Referring to FIG. 13, the electronic device 10 may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information suitable for operation of the processor 12 or the display module 11. When the processor 12 executes an application stored in the memory 13, image data signals (or, input image data) and/or input control signals may be delivered to the display module 11, and the display module 11 may process the signals provided to output image information via the display screen.

The power module 14 may include a power supply module, such as a power adapter or a battery unit, and a power conversion module that converts the power supplied by the power supply module to generate the power suitable for operation of the electronic device 10.

At least one of the above-described configurations of the electronic device 10 may be included within the display device according to the above-described embodiments. In addition, some of the functionally separate modules may be included within the display device and others may be provided separately from the display device. For example, the display device may include the display module 11, while the processor 12, the memory 13, and the power module 14 may be provided in the form of other devices within the electronic device 10 other than the display device.

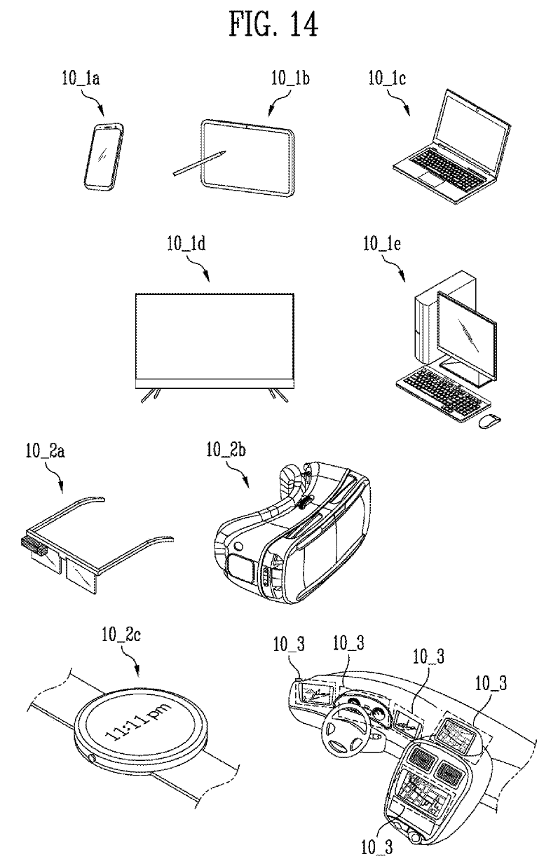

FIG. 14 schematically illustrates an electronic device according to some embodiments of the present disclosure.

Referring to FIG. 14, various electronic devices with a display device according to embodiments include an electronic device for displaying images, such a as a smartphones 10_1a, a tablet PC 10_1b, a laptop 10_1c, a television 10_1d, a desk monitor 10_1e, as well as a wearable electronic device including a display module such as a smart glasses 10_2a, a head-mounted display 10_2b, a smart watch 10_2c, and the like, and an automotive electronic device 10_3 including a display module such as a center information display (CID), a room mirror display, and the like located on an instrument panel, a center fascia, or a dashboard of an automobile.

According to a display device and an electronic device including the same according to embodiments of the present disclosure, stresses that cause defects may be reduced or eliminated by eliminating a step of the integrated circuit, and as a result, the quality of the product may be improved.

The foregoing referenced drawings and detailed descriptions of the present disclosure are mere examples of the present disclosure and are intended to illustrate the present disclosure but are not intended to limit the meaning or to restrict the scope of the present disclosure as claimed in the appended claims. Accordingly, those skilled in the art will understand that various modifications and other equivalent embodiments can be made from the foregoing referenced drawings and detailed descriptions. The true scope of technical protection of the present disclosure should therefore be determined by the technical spirit of the appended claims, with functional equivalents thereof to be included therein.

What is claimed is:

1. A display device, comprising:
a display panel comprising a display area and a non-display area;
an integrated circuit in the non-display area;
a pad part in the non-display area and spaced from the integrated circuit;
a circuit board on the integrated circuit and the pad part and comprising:
a main body portion spaced from the integrated circuit; and
a connecting body portion extending straight from the main body portion and spaced from the pad part;
an adhesive part adjacent to the integrated circuit, on the main body portion, and between the display panel and the circuit board; and
a compensation part between the circuit board and the pad part.

2. The display device according to claim 1, wherein the compensation part is between the connecting body portion and the pad part.

3. The display device according to claim 2, wherein the main body portion comprises:
a first main body on the adhesive part;
a second main body on the first main body and connected to the connecting body portion; and
a third main body on the second main body.

4. The display device according to claim 3, wherein the integrated circuit has a first thickness, and
wherein the adhesive part contacts three sides of the integrated circuit and has a second thickness that is greater than the first thickness.

5. The display device according to claim 3, wherein the integrated circuit has a first thickness, and
wherein the adhesive part is spaced from the integrated circuit and has a second thickness that is less than the first thickness.

6. The display device according to claim 5, wherein the main body portion is spaced from the integrated circuit in a thickness direction, in a length direction, in a direction opposite to the length direction, and in a width direction, and
wherein the connecting body portion is spaced from the pad part in the thickness direction.

7. The display device according to claim 5, wherein the main body portion is spaced from the integrated circuit in a thickness direction, in a length direction, in a direction opposite the length direction, in a width direction, and in a direction opposite the width direction, and
wherein the connecting body portion is spaced from the pad part in the thickness direction.

8. A display device, comprising:
a display panel comprising a display area and a non-display area;
an integrated circuit in the non-display area;
a pad part in the non-display area and spaced from the integrated circuit;
a circuit board on the integrated circuit and the pad part, and comprising:
a main body portion spaced from the integrated circuit; and
a connecting body portion extending straight from the main body portion and on the pad part; and
an adhesive part adjacent to the integrated circuit, on the main body portion, and between the display panel and the circuit board.

9. The display device according to claim 8, wherein the connecting body portion comprises:
a first connecting body extending straight from the main body portion;
a second connecting body below the first connecting body; and
an electrode between the second connecting body and the pad part.

10. The display device according to claim 9, wherein the main body portion comprises:
a first main body on the adhesive part;
a second main body on the first main body and connected to the first connecting body; and
a third main body on the second main body.

11. The display device according to claim 10, wherein the integrated circuit has a first thickness, and
wherein the adhesive part contacts three sides of the integrated circuit and has a second thickness that is greater than the first thickness.

12. The display device according to claim 10, wherein the integrated circuit has a first thickness, and
wherein the adhesive part is spaced from the integrated circuit and has a second thickness that is less than the first thickness.

13. The display device according to claim 12, wherein the main body portion is spaced from the integrated circuit in a thickness direction, in a length direction, in a direction opposite the length direction, and in a width direction.

14. The display device according to claim 12, wherein the main body portion is spaced from the integrated circuit in a thickness direction, in a length direction, in a direction opposite to the length direction, in a width direction, and in a direction opposite to the width direction.

15. The display device according to claim 8, wherein the main body portion comprises:
a first main body on the adhesive part and connected to the connecting body portion;
a second main body on the first main body; and
a third main body on the second main body.

16. The display device according to claim 15, wherein the main body portion is spaced from the integrated circuit in a thickness direction, in a length direction, in a direction opposite to the length direction, in a width direction, and in a direction opposite to the width direction.

17. The display device according to claim 8, wherein the connecting body portion comprises:
a first connecting body extending straight from the main body portion;
a second connecting body below the main body portion and the first connecting body; and
an electrode between the second connecting body and the pad part.

18. The display device according to claim 17, wherein the main body portion comprises:
a first main body on the adhesive part;
a second main body on the first main body and connected to the first connecting body; and
a third main body on the second main body.

19. The display device according to claim 18, wherein the main body portion is spaced from the integrated circuit in a thickness direction, in a length direction, in a direction opposite to the length direction, and in a width direction, and
wherein the second connecting body is spaced from the integrated circuit in a direction opposite to the width direction.

20. An electronic device, comprising:
a processor configured to provide input image data; and
a display device configured to display an image based on the input image data and comprising:
a display panel comprising a display area and a non-display area;
an integrated circuit in the non-display area;
a pad part in the non-display area and spaced from the integrated circuit;
a circuit board on the integrated circuit and the pad part and comprising:
a main body portion spaced from the integrated circuit; and
a connecting body portion extending straight from the main body portion and spaced from the pad part;
an adhesive part adjacent to the integrated circuit, on the main body portion, and between the display panel and the circuit board; and
a compensation part between the circuit board and the pad part.
